(19) United States
(12) Patent Application Publication
(10) Pub. No.: US 2012/0009694 A1
(43) Pub. Date: Jan. 12, 2012

(54) APPARATUS AND METHOD FOR MONITORING PRECURSOR FLUX

(75) Inventors: James E. Maslar, Silver Spring, MD (US); William A. Kimes, Gaithersburg, MD (US)

(73) Assignee: NATIONAL INSTITUTE OF STANDARDS AND TECHNOLOGY, Gaithersburg, MD (US)

(21) Appl. No.: 13/180,455

(22) Filed: Jul. 11, 2011

Related U.S. Application Data
(60) Provisional application No. 61/363,384, filed on Jul. 12, 2010.

(51) Int. Cl. G01N 21/61; H01L 21/66; B05C 11/00

(52) U.S. Cl. 438/16; 118/712; 118/708; 356/437; 257/E21.529

(57) ABSTRACT

An apparatus and method for monitoring precursor flux is disclosed herein. The apparatus comprises an optical cell configured for electromagnetic radiation spectroscopy and has a precursor reservoir or deposition chamber configured to provide a flow of a vapor deposition precursor therethrough, a first inner window sealing a first optical opening in the precursor reservoir or deposition chamber, a first outer window in optical communication with the first inner window, a first vacuum chamber disposed between the first inner window and the first outer window, a second inner window sealing a second optical opening in the precursor reservoir or deposition chamber, a second outer window in optical communication with the second inner window, a second vacuum chamber disposed between the second inner window and the second outer window. Each window being disposed to be in optical communication with one another, a electromagnetic radiation or light source, and an optical detector. A method of monitoring precursor flux comprises directing electromagnetic radiation through an outer window, a vacuum chamber, a first inner window, a volume within a cell body, and out of the cell body through a second inner window; and receiving the electromagnetic radiation from the second inner window with a sensor and sensing at least one parameter of a gas within the cell body.

### CROSS-REFERENCE TO RELATED APPLICATIONS

This application claims the benefit of U.S. Provisional Application No. 61/363,384, filed Jul. 12, 2010.

### STATEMENT REGARDING FEDERALLY SPONSORED RESEARCH OR DEVELOPMENT

This work is funded by the National Institute of Standards and Technology under the U.S. Department of Commerce.

### FIELD OF THE INVENTION

This invention relates to an apparatus and method for monitoring precursor flux and more particularly to an apparatus and method for monitoring low vapor pressure precursor flux during semiconductor deposition processes.

### BACKGROUND

The background information is believed, at the time of the filing of this patent application, to adequately provide background information for this patent application. However, the background information may not be completely applicable to the claims as originally filed in this patent application, as amended during prosecution of this patent application, and as ultimately allowed in any patent issuing from this patent application. Therefore, any statements made relating to the background information are not intended to limit the claims in any manner and should not be interpreted as limiting the claims in any manner.

One of the primary steps in the fabrication of modern semiconductor devices is the formation of a thin layer or film on a semiconductor substrate or other work piece by chemical vapor deposition (CVD) or atomic layer deposition (ALD). Conventional CVD processes supply reactive gasses to a substrate surface where heat-induced chemical reactions take place to produce a desired layer. Plasma-enhanced chemical vapor deposition (PECVD) process promotes excitation and/or dissociation of the reactant gases by the application of radio-frequency (RF) energy to a reaction zone near the surface, thereby creating a plasma. ALD is increasingly being utilized as a method of depositing thin (nano-meterscale), conformal layers that may be required for microelectronics applications such as high κ gate dielectric layers and diffusion barriers.

However, process development issues remain for deposition processes in many applications. For example, during CVD and ALD processes the ability to reproducibly deliver a known amount of precursor to the deposition surface may be critical to obtain the desired film properties. Also, it may be difficult to identify when the reservoir of a low vapor precursor is empty. To avoid running a deposition process with an empty reservoir, an operator may need to estimate the time a known amount of precursor will last, subtracting time for uncertainty in the delivery rate, and then replace the reservoir after that time. This method may be uneconomical as a substantial amount of the initial precursor loading may still be present in the reservoir. Additionally, especially for low vapor pressure liquids and solids, effective volatilization rates can change with time, especially with solid sources. Direct measurement of the reactant flux may provide a means for identifying reservoir depletion thereby avoiding running a deposition process with an empty reservoir without leaving a substantial amount of precursor in the reservoir. Direct measurement may also provide for a means to mitigate the effects of volatilization rates changing with time.

During CVD and ALD processes, the ability to reproducibly deliver a known amount of reactant to the deposition surface can be critical to obtaining the desired film properties. For low vapor pressure liquids and solids, it may be difficult to reproducibly deliver known amounts of a reactant. One solution to the problem of reproducible delivery of low vapor pressure precursors may be the direct measurement of the reactant flux in real time. The direct measurement of reactant flux may offer a number of advantages for process control including a more precise determination of the time-dependent flow rate and of the total amount of precursor that has been consumed.

Conventional real-time monitoring systems of thin film deposition processes such as sputtering, thermal evaporation, etc., have included ellipsometry, transmission, reflectance, or mass gain by QCM (Quartz Crystal Microbalance). In some instances, monitoring may be done on witness samples introduced into the process, however real-time monitoring in transmission mode may be problematic. Reflectance measurements also present unique problems with internal reflections that limit measurement accuracy.

Optical measurements based on absorption processes in various wavelength regions of the electromagnetic spectrum may provide direct real-time measurement of precursor flux that overcomes some of the disadvantages associated with the prior art. For example, Fourier Transform Infrared (FT-IR) spectroscopy has been used to perform online gas analysis of a multi-component gas flows. However, the design of an optical cell may require a long optical path length requiring multiple reflections in the optical cell to maximize the signal-to-noise ratio of the data. In general, this may not be the optimum configuration for minimizing gas residence time and maintaining uniform heating of the gas. Additionally, the optical ports or windows in a precursor flow stream or deposition chamber for FT-IR spectroscopy may need to be heated to minimize precursor deposition or condensation on the windows which may introduce signal noise from beam steering, especially with low vapor pressure precursor deposition processes.

What is needed is an apparatus and method for monitoring precursor flux that may overcome at least some of the deficiencies of the prior art.

### SUMMARY

In at least one aspect of the present disclosure, an apparatus configured to monitor low vapor pressure precursor flux in a semiconductor deposition process is disclosed. The apparatus comprises an optical cell configured for optical spectroscopy. The optical cell comprises a precursor reservoir or deposition chamber configured to provide a flow of a vapor deposition precursor therethrough, a first inner window sealing a first optical opening in the precursor reservoir or deposition chamber, a first outer window in optical communication with the first inner window, a first vacuum chamber disposed between the first inner window and the first outer window, a second inner window sealing a second optical opening in the precursor reservoir or deposition chamber, a second outer window in optical communication with the second inner window, a second vacuum chamber disposed between the second inner window and the second outer window. The first inner window, the first outer window, the second inner window, and the second outer window each are disposed to be in optical communication with one another. The apparatus further comprising a electromagnetic radiation or light source disposed in optical communication with the first outer window or the second outer window and an optical detector disposed in optical communication with the other of the first outer window or the second outer window.

In at least one other aspect of the present disclosure, an apparatus configured to monitor precursor flux in a semiconductor deposition process is disclosed. The apparatus comprises a cell configured for electromagnetic radiation spectroscopy. The cell comprises a precursor reservoir or deposition chamber configured to provide a flow of a vapor deposition precursor therethrough, a first inner window sealing a first optical opening in the precursor reservoir or deposition chamber, a first outer window in optical communication with the first inner window, a vacuum chamber disposed between the first inner window and the first outer window, and a second inner window sealing a second optical opening in the precursor reservoir or deposition chamber. The first inner window, the first outer window, and the second inner window, each are disposed to be in optical communication with one another. The apparatus further comprises an electromagnetic radiation source in optical communication with the first outer window or the second inner window and an electromagnetic radiation detector in optical communication with the other of the first outer window or the second inner window.

In at least one additional aspect of the present disclosure, a method of monitoring precursor flux is disclosed. The method comprises the steps of: a) directing energy through an outer window, a vacuum chamber, an first inner window, a volume within a cell body configured to have precursor therein, and out of the cell body through a second inner window; b) receiving the energy from the second inner window with a sensor configured to sense at least one parameter of the gas within the cell body; and c) sensing at least one parameter of the gas within the cell body.

### BRIEF DESCRIPTIONS OF THE DRAWINGS

The following figures, which are idealized, are not to scale and are intended to be merely illustrative and non-limiting.

FIG. 1 is a schematic representation of a deposition process that shows the incorporation of an optical cell of the present disclosure;

FIG. 2 is a cross-sectional view of a portion of an optical cell of the present disclosure;

FIG. 3 is an exploded view of an optical cell of the present disclosure;

FIG. 4 is a low temperature energy absorbance plot showing energy absorbance of a carrier, with and without the outer windows of the optical cell shown in FIG. 3;

FIG. 5 is a high temperature energy absorbance plot showing energy absorbance of a carrier, with and without the outer windows of the optical cell shown in FIG. 3; and

FIG. 6 is an energy absorbance plot of a gas flow in a deposition chamber showing energy absorbance of the gas flow upon introduction of an organometallic precursor into the gas flow, using an optical cell with inner and outer windows.

### DETAILED DESCRIPTION

A detailed description will now be provided. Each of the appended claims is to be recognized as including equivalents to the various elements or limitations specified in the claims. Depending on the context, all references below to the “invention” or disclosure may in some cases refer to certain specific aspects only. In other cases it will be recognized that references to the “invention” will refer to subject matter recited in one or more, but not necessarily all, of the claims. Each of the inventions is described in greater detail below, including specific aspects, versions and examples, but the disclosure is not limited to these aspects, versions or examples, which are included to enable a person having ordinary skill in the art to make and use the inventions when the information in this patent is combined with available information and technology.

Various terms as used herein. To the extent a term used in a claim is not defined herein, it should be given the broadest definition persons in the pertinent art have given that term as reflected in printed publications and issued patents at the time of filing. Additionally, unless otherwise specified, all compounds or examples described herein may be substituted or unsubstituted and the listing of compounds or examples includes derivatives thereof. Further, various ranges and/or numerical limitations may be expressly stated below. It should be recognized that unless stated otherwise, it is intended that endpoints are to be interchangeable and any ranges shall include iterative ranges falling within the expressly stated ranges or limitations.

It was discovered that beam steering may be a significant source of noise in the measurements of precursors for deposition processes, especially precursors comprising low vapor pressure liquids and solids in an elevated temperature, laminar flow atomic layer deposition reactor. Disclosed herein is an apparatus and method for monitoring precursor flux that may provide for direct real-time measurement of the reactant flux which may provide for monitoring and reproducible delivery of reactant flux for a deposition process. The reactant flux monitor may be configured for in-line flow and may provide for high sensitivity optical measurement of low vapor pressure precursors. An optical cell disclosed herein may comprise beam steering/scintillation reducers and provide for a method of beam steering reduction in high sensitivity optical spectroscopy which may improve the detection of concentration of precursor in a gas stream or within a deposition chamber.

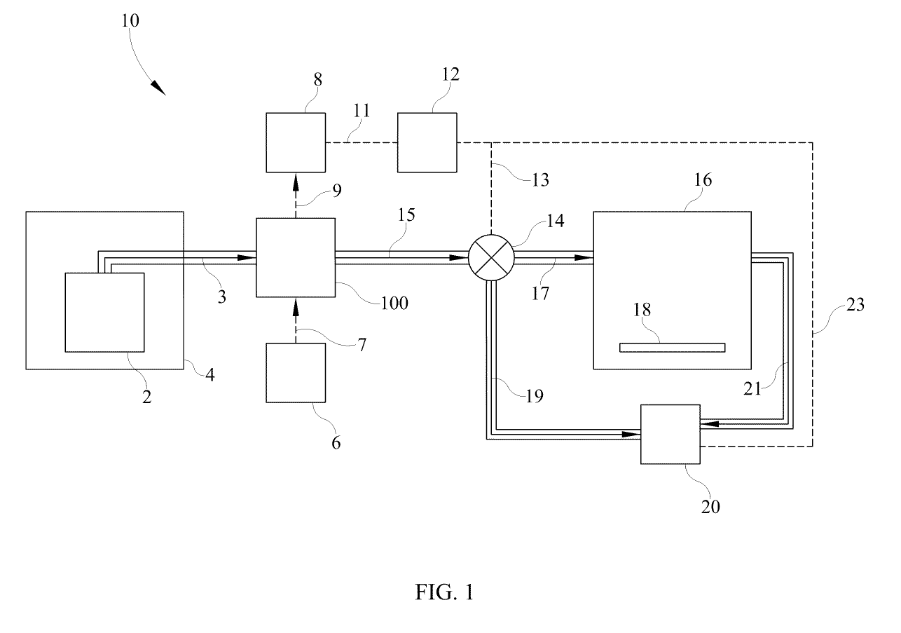

Referring now to the figures, FIG. 1 is a schematic representation of a deposition process 10 that shows the incorporation of an optical cell 100 of the present disclosure. Optical cell 100 is disposed to monitor reactant vapors before reaching a deposition chamber 16. The reactant vapor source 2 may be maintained in an oven 4, however, the use of an oven may not be necessary for reactants which are sufficiently volatile at room temperature. If an oven 4 is used, reactant transport lines throughout this process 10 may be heated to maintain the temperature of the reactant.

A transport line 3 leads to optical cell 100. Optical cell 100 may comprise an FT-IR spectrometer optically coupled to optical cell 100 and configured to analyze the concentration and/or composition of vapor flowing through optical cell 100 before it travels to deposition chamber 16. Electromagnetic radiation or light source 6 may be configured and disposed to emit electromagnetic radiation which may propagate to optical cell 100 along optical path 7. Electromagnetic radiation may then pass through optical cell 100 and propagate to optical sensor 8 along optical path 9.

Semiconductor deposition process 10 may comprise a controller 12 in data communication with optical detector 8, via communication line 11. Controller 12 may be configured to control the flux of the precursor into semiconductor deposition chamber 16, pump 20, and/or one or more operating parameters of semiconductor deposition chamber 16. For example, optical sensor 8 may send information to process controller 12 which may control a valve 14. Process controller 12 may operate valve 12 based upon the information it receives from optical detector 8. Precursor transport line 15 leads from optical cell 100 to valve 14. The outputs from valve 14 are precursor transport line 17, leading to deposition chamber 16, and precursor transport line 19, leading to the system pump 20. A precursor transport line 21 leads from deposition chamber 16 to system pump 20, for controlling the operating pressure of deposition chamber 16.

When the reactant vapor, or precursor flux, flowing in the optical cell 100 is analyzed, information may be passed to process controller 12 indicating whether precursor, contaminants, or decomposition products are present. If little or no precursor is detected with optical detector 8, valve 14 may be closed, an alarm may sound, and/or pump 20 may be disengaged. If a composition of reactant vapor or flux which may be harmful to deposition chamber 16 or deposition substrate 18, within deposition chamber 16, is detected with optical detector 8, process controller 12 may send a signal to operate valve 14 to cause reactant vapor to flow through transport line 19 to pump 20, rather than through line 17 to deposition chamber 16. If the precursor flux is detected with optical detector 8 and the composition of the reactant vapor or precursor is appropriate, valve 14 may be operated to direct the precursor through transport line 17 to deposition chamber 16 and proceed to reaction with substrate 18. While deposition process 10 has been generally disclosed herein, those skilled in the art will recognize that the invention may be practiced with modification. For example, controller 12 may be in communication with pump 20, via communication line 23, and may regulate the pressure within deposition chamber 16. Other and different feedback controls may be incorporated in deposition process of the present disclosure which may control precursor flow rate or temperatures of process components, for example.

In at least one aspect of the present disclosure, optical cell 100 may be configured and disposed to monitor a precursor within deposition chamber 16. For example, deposition chamber 16 having substrate 18 therein may be disposed within a cell body of optical cell 100.

In at least one other aspect of the present disclosure, a method for feedback control of the amount of a low vapor pressure precursor that is delivered during a semiconductor deposition process, e.g., chemical vapor deposition (CVD) and atomic layer deposition (ALD) is provided. An in-line, heated gas flow cell may permit high sensitivity optical measurements of the gas stream with a low degree of gas entrainment. Coupled with an optical diagnostic appropriate for the precursor of interest, the process may enable an operator to determine the amount of precursor being delivered to a deposition surface which may provide the basis for integrated deposition process control and may allow for more precise control of film properties and for more efficient use of precursors.

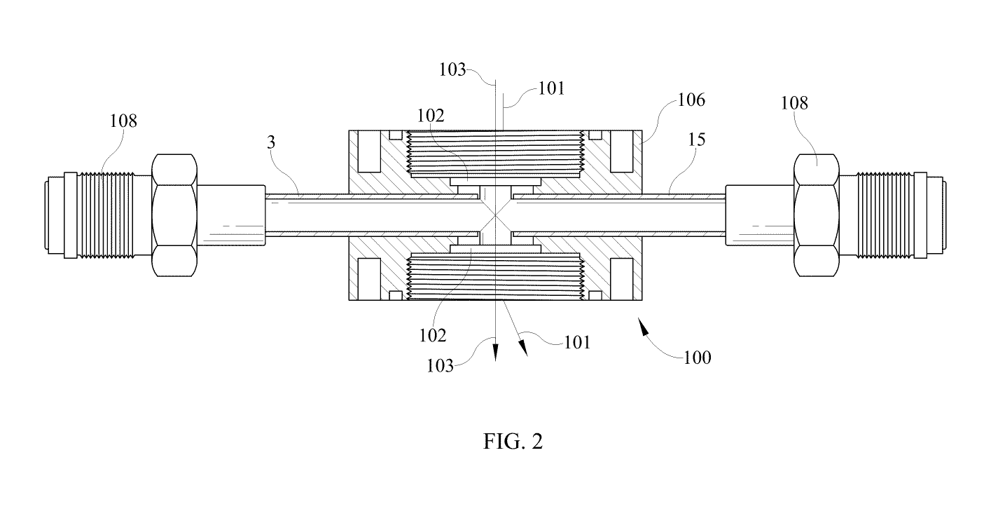

FIG. 2 is a cross-sectional view of a portion of optical cell 100 of the present disclosure. Optical cell 100 may be configured to minimize effects of beam steering. Beam steering may increase the baseline noise level of an optical detector, making it more difficult to measure species present at low concentrations, e.g., low vapor pressure precursors. Optical cell 100 may be an in-line gas flow cell configured for detecting the low vapor pressure organometallic compounds, for example tetrakis(ethylmethylamido)hafnium. Optical cell 100 may comprise a cell body with minimum internal volume, minimizing residence time within optical cell 100.

As shown in FIG. 2, optical cell 100 may comprise a connector 108 on one or both transport lines 3 and 15. Connectors 108 may comprise a connection to a Vacuum Coupling Radlow (also referred to as a VCR®). A VCR® is a metal gasket face seal which is a standard sealing mechanism known in the art and is produced by Swagelok Co., of Solon, Ohio, USA. It is to be understood that other and different fittings or connectors that are known in the art may be disposed with transport lines 3 and 15 and that connectors 108 may need not be incorporated within optical cell 100.

Transport lines 3 and 15 enable the flow through of a precursor through cell body 106. Cell body 106 may have a substantially consistent flow through portion configured to induce laminar flow of precursor therethrough. Cell body 106 has inner optical windows 102 recessed within cavities in cell body 106. Optical windows 102 are disposed to be in optical communication with each other and the inner portion of cell body 106. Optical path 103 shows linear propagation of electromagnetic radiation or light through optical windows 102 and cell body 106. Optical path 101 shows a curved or bent propagation of electromagnetic radiation or light through optical windows 102 and cell body 106. This bending or curving of electromagnetic radiation or light, beam steering, may occur adjacent an outer surface of optical windows 102. For example, the placement of recessed optical ports or windows 102 into a heated block or cell body 106 may result in heating of the ambient gas around the optical ports which, in turn, may result in turbulent density variations in the ambient gas around the optical ports. This may cause beam steering of an optical beam propagating through the optical cell. This, in turn, may result in a time-dependent beam intensity on an optical detector which may significantly increase the baseline noise level, making it more difficult to measure species present at low concentrations, e.g., low vapor pressure precursors. Therefore, in at least one aspect of the present disclosure, optical cell 100 is configured to minimize beam steering of a electromagnetic radiation or light beam propagating therethrough.

It may be advantageous for optical cell 100 to enable the gas flow therethrough and temperature therein, during semiconductor deposition processes, to approximate the gas flow and temperature in gas delivery lines 3 and 15, e.g., a heated steel tube. Hence, the design geometry of the inner flow through portion of cell body 106 may provide a short gas residence time which may minimize gas delivery time, thereby maximizing the abruptness of film interfaces while minimizing the potential for precursor decomposition. In addition, elevated temperature operation may be necessary to minimize precursor condensation (low vapor pressure precursors may be delivered at elevated temperatures to increase the amount of precursor being delivered). In at least one aspect of optical flow cell 100 disclosed herein is designed to closely approximate gas flow through a tube as shown in FIG. 2.

The cross sectional view of the flow cell body 106 may be configured to minimize cell volume (and gas residence time) as gas flows through a cylindrical hole in the cell body 106. In addition, the optical ports 102 may be recessed into the cell body to minimize the distance from the interior optical surface to the cell interior flow though volume. Standard tube connectors 108, e.g., VCR® connections, may be attached to one or both ends of optical cell 100 to further minimize gas entrainment and facilitate installation into gas delivery systems.

Since the flow cell body 106 may need to be heated to prevent reactant condensation, the optical ports 102, which contain the process gas, may also need to be heated. The placement of recessed optical ports 102 into a heated block or cell body 106 may result in heating of the ambient gas around the optical ports which, in turn, may cause beam steering of an optical beam propagating through the cell as shown with optical path 101.

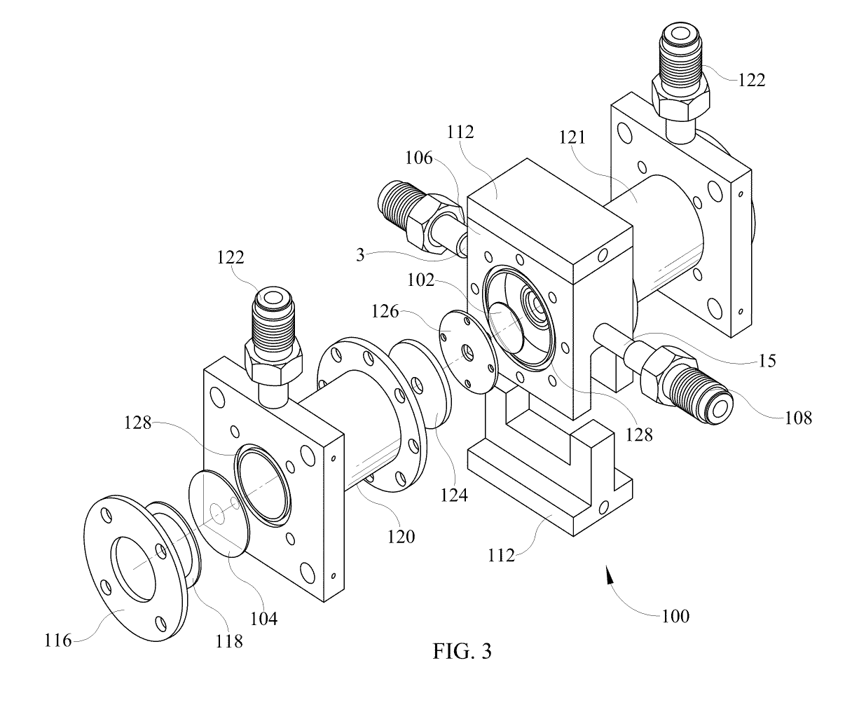

FIG. 3 is an exploded view of optical cell 100 of the present disclosure which may have a small precursor volume in cell body 106 and may enable substantially uniform heating of a gas in cell body 106. Optical cell 100 may enable the reduction of beam steering by employing an optical port arrangement involving one or two pairs of transparent windows (one inner window 102 and one outer window 104 in each pair) with an intervening vacuum chamber. Inner optical windows 102 may be located in a heated zone configured to contain the process gas, within optical cell body 106, while outer optical windows 104 may be located in an area free of significant thermal gradients in the ambient gas. Outer windows 104, cool windows, may be thermally isolated from the inner windows 102, hot windows. For example, a volume between each pair of inner and outer windows 102 and 104 may be evacuated so that the gas density in this volume is insufficient to result in significant beam steering, as well as to minimize localized window cooling due to convection. In at least one aspect of the present disclosure, a vacuum between inner and outer windows 102 and 104 may not be needed for the detection of some precursors.

Optical cell 100 may comprise a first vacuum chamber 120 and/or a second vacuum chamber 121. It is to be understood that the incorporation of a single vacuum chamber may enable optical cell 100 to mitigate beam steering by an amount necessary to detect some deposition precursors and is within the scope of the claims herein. One of the vacuum chambers, vacuum chamber 120, is shown in an exploded view in FIG. 3. Connecting disc 116 is configured to hold window holder 118 against outer window 104 and connect outer window 104 to vacuum chamber 120. A groove 128 may be configured to dispose a seal therewith for sealing window 104 about an inner annular volume of vacuum chamber 120. For example, an elastomer O-ring seal may be disposed in groove 128. However, is to be understood that other seals as are known in the art may be used to seal window 104 with vacuum chamber 120 and that groove 128 may need not be incorporated with vacuum chamber 120. For example, ceramic-to-meal window sealing technologies may provide an alternative to an elastomer O-ring seal.

Vacuum port 122 may be in flow communication with an inner volume of vacuum chamber 120 and may be configured and disposed to evacuate air therefrom. Vacuum port 122 may comprise a VCR® or other fitting or connector configured to impart a vacuum within vacuum chamber 120.

Vacuum chamber 120 may be sealed with cell body 106. Connecting disc 124 may be disposed against window holder 126 and window holder 126 may be configured and disposed to hold window 102 within a cavity or recess in cell body 106. Each connecting disc, 116 and 124, each window holder, 118 and 126, and the inner volume of vacuum chamber 120 are configured and disposed to provide optical communication with an outside electromagnetic radiation or light source, between each window 104 and 102, and through an inner volume of cell body 106. Cell body 106 may be configured to dispose heaters 112. Heaters 112 may be electrical heaters and may be configured and disposed to heat cell body 106 and inner windows 102 to a desired operating temperature. Heaters 112 may be controlled with controller 12.

In at least one aspect of the present disclosure, cell body 106 may be configured to dispose a deposition chamber. Therefore, optical cell 100 may be configured and disposed to monitor the flux of deposition precursor within a deposition chamber. In at least one aspect of the present disclosure, the precursor reservoir in cell body 106 may be a deposition chamber.

A method of detecting or monitoring precursor flux disclosed herein may improve the signal-to-noise ratio (SNR) in high sensitivity optical spectroscopy of gas cells at elevated temperatures in which a beam of electromagnetic radiation or light propagates through both an ambient gas and an analyte or precursor in the gas cell. Beam steering of the electromagnetic radiation or light due to thermal gradient-induced refractive index variations in the ambient gas may be a significant source of noise when optical ports are located in close proximity to heated zones. The optical port arrangement disclosed herein comprising a pair of transparent windows, 102 and 104, with an intervening vacuum, may reduce beam steering of electromagnetic radiation or light. Having one inner window, 102, located in a heated zone and separated by a vacuum from a second (thermally isolated) outer window, 104, located in an area free of significant thermal gradients, may reduce beam steering by an amount sufficient to monitor low vapor pressure precursors.

To reduce beam steering, an optical port arrangement involving a pair of transparent windows, an inner window 120 and an outer window 104, with an intervening vacuum chamber may be employed (for transmission measurements, two optical ports may be employed for a total of two pairs of windows). One window 102 is located in a heated zone while the second window 104 is located in an area free of significant thermal gradients in the ambient gas. Outer window 104 is thermally isolated from inner window 102 and the volume between the two windows may be evacuated wherein the gas density in this volume may become insufficient to produce significant variations in the refractive index, thereby minimizing beam steering. For example, an intervening vacuum may be used to reduce gas density and reduce convective heating. However, an improvement of cell performance may be realized without a vacuum between the inner windows 102 and outer windows 104, as compared to the cell performance of prior art optical cells not having outer windows 104. Therefore, enclosing the volume between the two windows, 102 and 104, without an intervening vacuum may be sufficient to minimize some density gradients and is within the scope of the present disclosure.

A method of detecting or monitoring precursor flux comprises directing energy, such as electromagnetic radiation or light from a laser or broadband IR source (such as from an FT-IR spectrometer), for example, through an outer window 102, a first vacuum chamber 120, an inner window 104, a precursor reservoir or deposition chamber or volume within cell body 106, a second inner window 102, a second vacuum chamber 121, a second outer window 104, and to a detector 8. The process may further comprise heating cell body 106 and inner windows 102 and maintaining the temperature of the outer windows 104 below a temperature of the inner windows 102. Advantageously, the temperatures of the outer windows 104 are maintained proximate an ambient temperature. A final step of detecting the directed energy emitted from the second outer window may provide for FT-IR spectroscopy, tunable laser absorption spectroscopy, or other detection means as is known in the art, of a gas within or flowing through the precursor reservoir or deposition chamber or inner volume of cell body 106.

### EXAMPLES

Objects and advantages of this invention may be further illustrated by the following examples, but the particular materials and amounts thereof recited in these examples, as well as other conditions, such as temperatures, and details, should not be construed to unduly limit this invention.

The following examples may provide for an apparatus and method of beam steering reduction in high sensitivity optical spectroscopy such as an in-line flow cell for high sensitivity optical measurement of low vapor pressure precursors during semiconductor deposition processes.

### Example 1

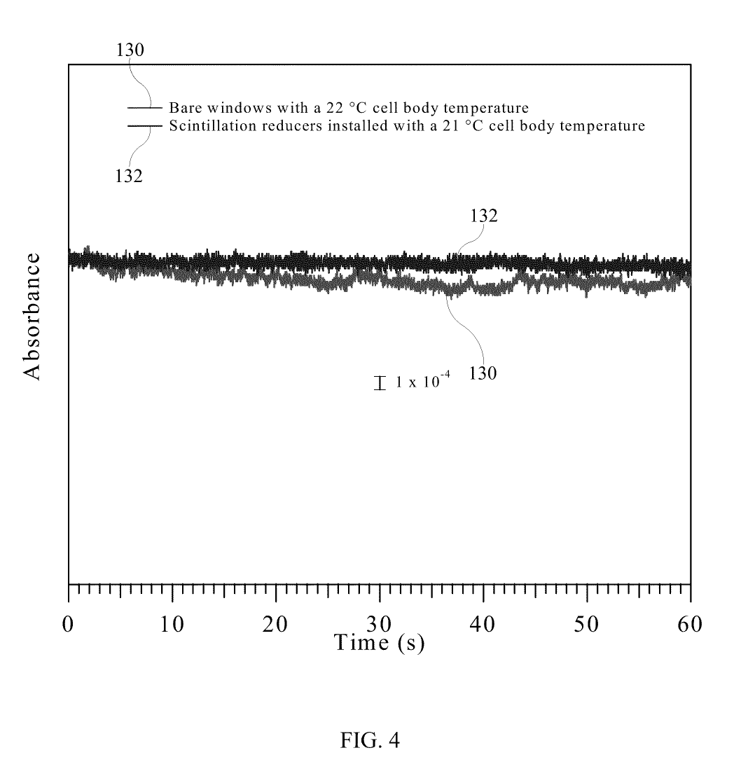

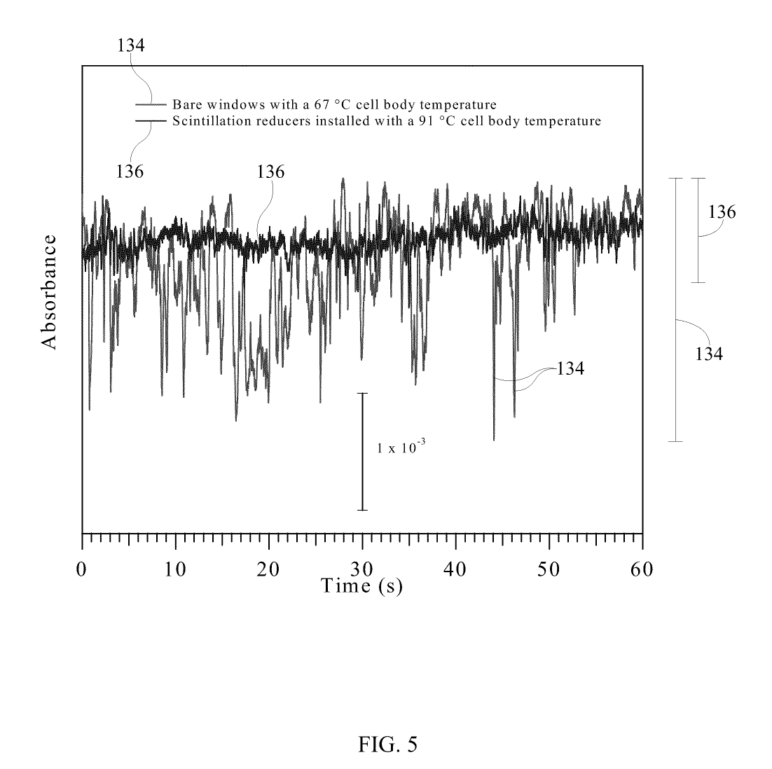

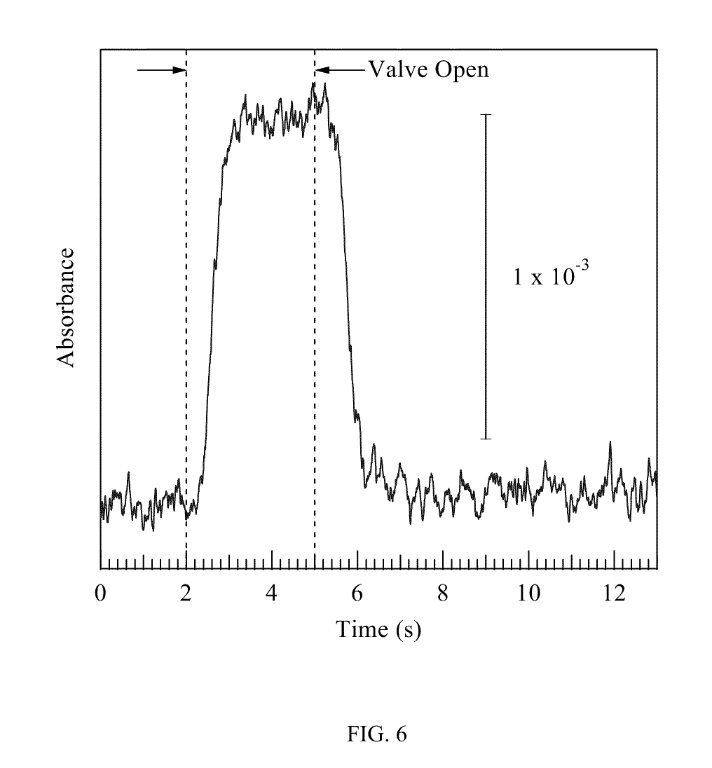

Baseline absorbance levels were measured for a series of optical cell temperatures and optical cell configurations using a near-infrared (IR) distributed feedback diode laser operating at 1.392 μm. Measurements were performed in ultra-high-purity grade helium (99.999% pure) flowing at a nominal total flow rate at standard temperature and pressure (0° C. and 101.3 kPa) of 75 mL/min. The laser current was modulated at 40 kHz and the laser transmission through the optical cell was measured using a 10 MHz-bandwidth InGaAs detector. The detector signal was filtered using a lock-in amplifier and the lock-in output at the modulation frequency was digitized at 200 Hz. The absorbance A was calculated using the expression:

$$A = - {log}_{10} ( \frac{{P}_{r}}{{P}_{r}^{0}} )$$

where P₁ and Pᵣ⁰ both represent the radiant power transmitted through the optical cell and the Pᵣ⁰ value was obtained by taking the mean of 201 values of the digitized lock-in amplifier signal corresponding to the time interval 1 s to 3 s. The optical cell was configured with CaF₂ windows that had a 0.5 degree wedge (to reduce étaloning effects). Four cell configurations and temperatures were compared:
1. Optical cell configured with bare windows with a cell body temperature of 22° C. (130, FIG. 4)
2. Optical cell configured with scintillation reducers with a cell body temperature of 21° C. (132, FIG. 4)
3. Optical cell configured with bare windows with a cell body temperature of 67° C. (134, FIG. 5)
4. Optical cell configured with scintillation reducers with a cell body temperature of 91° C. (136, FIG. 6)

The peak-to-peak absorbance value range for a 60 s time interval was estimated and represents the typical baseline absorbance level that is expected for the various optical cell configurations described above. The baseline absorbance level was ˜1×10⁻⁴ absorbance units for configurations 1 and 2 which demonstrates the best expected baseline absorbance level for this experimental configuration. The baseline absorbance level was ˜2×10⁻³ absorbance units for configuration 3 which demonstrates the degradation in baseline absorbance level at an elevated temperature without outer windows 104. The baseline absorbance level was ˜4×10⁻⁴ absorbance units for configuration 4 shows that the use of the outer windows 104 may improve the baseline absorbance level achievable in this experimental configuration.

In this example, near-infrared distributed feedback diode laser transmission through flow cells, with and without the installation of beam steering/scintillation reducers, at various temperatures, were performed. FIG. 4 shows the results of a low temperature monitoring cycle, with and without outer windows 104. Absorbance plots 130 and 132 show the absorbance of a near-IR distributed feedback diode laser operating at 1.392 μm while flowing helium through an optical cell body 106 at approximately 22° C. Absorbance plot 130 shows absorbance of energy through an optical cell without outer windows 104 while absorbance plot 132 shows absorbance of energy through an optical cell having outer windows 104, as shown in FIG. 3. Absorbance plots 130 and 132 show that the magnitude of the background noise level is approximately the same with or without installation of the outer windows 104 or vacuum chambers 120 and 121. The baseline absorbance level of ˜1×10⁻⁴ absorbance units was shown to not significantly change, at substantially ambient temperature, with the installation of outer windows 104.

FIG. 5 shows the results of a high temperature monitoring cycle, with and without outer windows 104. Absorbance plots 134 and 136 show the absorbance of a near-IR distributed feedback diode laser operating at 1.392 μm while flowing helium through an optical cell body 106 at elevated temperatures. Absorbance plot 134 shows absorbance of energy through an optical cell without outer windows 104 and having a cell body temperature of approximately 67° C. Absorbance plot 136 shows absorbance of energy through an optical cell with outer windows 104, as shown in FIG. 3, and having a cell body temperature of approximately 91° C. This data shows that upon heating the cell to only about 67° C., without the outer windows in place, the absorbance level increased to greater than ˜1×10⁻³ absorbance units. In contrast, upon heating to 91° C., with the outer windows 104 in place, the absorbance level was shown to be much less than ˜1×10⁻³ absorbance units. Therefore, the use of the outer windows 104 may enable measurements at significantly lower absorbance levels which may permit detection of precursors at lower concentrations than when the outer windows are not used.

### Example 2

This example shows the minimum baseline absorbance levels needed to detect a concentration of a prototypical metalorganic compound may be achieved with at least one aspect of the optical cell of the present disclosure. Measurements of the metal alkylamide compound tetrakis(ethylmethylamido) hafnium (TEMAH) during injection into an ALD chamber were made. TEMAH absorbance as a function of time was recorded in flowing TEMAH with a helium carrier gas using a mid-IR quantum cascade laser (QCL) operating at 10.21 μm. The QCL was amplitude modulated at 50 kHz using a photoelastic modulator and a CdS quarter wave plate. To compensate for laser output intensity variations, the beam was divided into two beams of nominally equal power using a ZnSe beamsplitter. The reflected portion of the beam from the beamsplitter, referred to as the probe beam, was directed through the ALD chamber to a room-temperature, optically-immersed (to a hyperhemispherical GaAs lens) photovoltaic multi-junction mercury cadmium zinc telluride detector with a 1 mm×1 mm active area. The transmitted portion of the beam, referred to as the reference beam, was directed to a second nominally identical detector. Each detector signal was filtered using a lock-in amplifier and the lock-in output at the modulation frequency was digitized at 200 Hz. TEMAH was introduced by flowing ultra-high-purity grade helium (99.999% pure) through a stainless steel bubbler containing TEMAH at a nominal total flow rate at standard temperature and pressure (0° C. and 101.3 kPa) of 75 mL/min. The TEMAH bubbler was maintained at a temperature of 75° C. which corresponds to a TEMAH vapor pressure of ˜0.39 torr. The absorbance, A, was calculated using the expression:

$$A = - {log}_{10} ( \frac{{P}_{probe} / {P}_{ref}}{{P}_{probe}^{0} / {P}_{ref}^{0}} ) = - log ( \frac{{P}_{r}}{{P}_{r}^{0}} )$$

where Pᵣ is the ratio of the radiant power transmitted through the chamber incident on the probe detector (P_{probe}) to the radiant power incident on the reference detector at the corresponding time (P_{ref}) and Pᵣ⁰ is the ratio of the radiant power transmitted through the chamber when TEMAH is nominally absent (P_{probe}⁰) to the radiant power on the reference detector at the corresponding time (P_{ref}⁰). The Pᵣ⁰ value was obtained by taking the mean of 200 values of the ratio of the probe voltage to reference voltage corresponding to the time interval 0.5 s to 1.495 s during an initial 2 s helium purge. FIG. 6 shows the absorbance as a function of time during TEMAH injection into the 10 cm pathlength deposition chamber. For these TEMAH injection conditions, the concentration of TEMAH present in the reactor corresponds to a maximum absorbance level of ˜1×10⁻³. To estimate the corresponding absorbance level that would be observed in the optical cell, the mole concentration, c (mol m⁻³), is first determined from the observed absorbance level using the expression:

A=∈cl

where ∈ is the molar absorptivity (m² mol⁻¹) and l is the optical path length (m). In our laboratory, the TEMAH molar absorptivity at 10.21 μm, which corresponds to the most intense absorption in the TEMAH spectrum, was determined to be 43 m² mol⁻¹. The optical pathlength in the ALD chamber was 0.107 m. For these conditions, c=˜2×10⁻⁴ mol m⁻ in the ALD chamber. In the case of the optical cell described in this patent application, the optical pathlength is 9.65×10⁻³ m. Since the optical cell has a smaller volume, the estimated concentration in the optical cell will be increased by the ratio of the cross sectional areas of the ALD chamber to optical cell which is equal to ˜123. The corresponding estimated absorbance value is therefore equal to (43 m² mol⁻¹)×(123×2×10⁻⁴ mol m⁻³)×(9.65×10⁻³ m)=−1×10⁻² absorbance units. Hence, to employ optical absorption-based measurements for TEMAH delivery measurements under the conditions described here, it is necessary to be able to measure absorbance levels of better than ˜1×10⁻² absorbance units. Molar absorptivity values for a range of metalorganic compounds are not readily available. However, it is a reasonable assumption that other metal alkylamide compounds exhibit similar molar absorptivity values as TEMAH and therefore the aspects of the optical cell disclosed herein may be configured to measure a variety of deposition precursors.

In this example, an optical cell of the present disclosure was configured and disposed to detect a precursor within a deposition chamber. Two pairs of inner and outer windows with an intervening vacuum were disposed on the deposition chamber for this example. FIG. 6 shows the results of a high temperature monitoring cycle of the deposition chamber. The data was recorded while flowing Tetrakis(ethylmethylamino)Hafnium, TEMAH, through the deposition chamber with a helium carrier gas using a mid-IR quantum cascade laser operating at 10.21 μm. TEMAH was introduced by flowing helium through a stainless steel bubbler containing TEMAH which was maintained at a temperature of approximately 75° C., which corresponds to a TEMAH vapor pressure of ˜0.39 torr. FIG. 6 shows that precursors having absorbance levels below ˜1×10⁻³ absorbance units may be measured. Therefore, aspects of the present disclosure may enable absorbance-based measurements to monitor delivery of at least one prototypical organometallic compound.

During CVD and ALD processes, the ability to reproducibly deliver a known amount of precursor to the deposition surface can be critical to obtain the desired film properties. For low vapor pressure liquids and solids (e.g. organometallic precursors), it may be difficult to reproducibly deliver known amounts of a reactant because effective volatilization rates can change with time, especially with solid sources. One solution to the problem of reproducible delivery of low vapor pressure precursors may be the direct measurement of the reactant flux. The direct measurement of reactant flux may be advantageous for process control including a precise determination of the time-dependent flow rate and of the total amount of precursor that has been consumed. The disclosure herein may provide a basis for direct measurement of the precursor flux.

At least one aspect of the present disclosure addresses beam steering originating from density gradients in the optical cell ambient. In at least one other aspect of the present disclosure, the gas dynamics of a tube is maintained through the optical cell which may reduce turbulent flow of a precursor flowing through the optical cell, hence reduce beam steering due to the flow of the precursor. In at least one further aspect, the optical path length through the cell is short as reflection mirrors may not be needed for maximization of signal-to-noise ratio. Rapid measurements, enhanced detection schemes, e.g., phase-sensitive detection, may be utilized with the apparatus and method of the present disclosure. The optical cell disclosed herein may incorporate non-metallic surfaces to which the precursor will be exposed to minimize contamination issues. However, some reactive surfaces/species may be passivated by the precursor and therefore non-metallic surfaces may not be required in all aspects of the present disclosure.

Optical measurements for in situ diagnostics may be based on absorption processes in various wavelength regions of the electromagnetic spectrum. However, all or most all such measurements involve an optical cell to provide diagnostic access to the process gas. Current designs of optical cells may comprise a long optical path length (sometimes with multiple reflections in the cell) to maximize the signal-to-noise ratio of the data. In general, this may not be the optimum configuration for minimizing gas residence time and maintaining uniform heating of the gas. The optical cell design disclosed herein may have a small volume and also may permit uniform heating of a gas in the cell. In addition, by incorporating a second set of windows or outer windows to minimize the effects of beam steering, high sensitivity optical measurements may be performed without the need for a long optical path length. Aspects of the present disclosure may permit optical access to the analyte gas without significantly perturbing the gas flow dynamics and temperature fields of the gas cell. Aspects of the present disclosure may permit faster processes to be investigated for a given signal-to-noise ratio and/or permit the use of smaller, less expensive detectors.

Aspects of the present disclosure may preclude the use a second beam of electromagnetic energy, coincident with the first beam and that is not absorbed by the analyte but is affected by beam steering, for normalization of the intensity of the first beam, thereby reducing experimental complexity. Aspects of the disclosure herein may be utilized to investigate analytes exhibiting spectral transitions with most any line width without the need for wavelength modulation spectroscopy. Wavelength modulation spectroscopy comprises harmonic detection of the detected radiation wherein the first harmonic of the detected signal is used to correct higher harmonics for variations in the beam intensity. However, wavelength modulation spectroscopy with harmonic detection may not be applied to larger molecules that do not exhibit narrow, resolved spectral transitions. Conversely the apparatus of the present disclosure may be applied to larger molecules that do not exhibit narrow, resolved spectral transitions.

Aspects of the present disclosure may provide a method to improve the signal-to-noise ratio in high sensitivity optical spectroscopy of gas cells at elevated temperatures in which a beam of electromagnetic radiation propagates through both an ambient gas and an analyte in the gas cell. The method for improving signal-to-noise ratio involves reducing beam steering of the electromagnetic radiation in the ambient gas. If the gas cell is at a higher temperature than the ambient gas and at a reduced pressure compared to the ambient gas (e.g., microelectronics vapor deposition systems), then beam steering due to temperature gradients in the ambient gas can significantly degrade signal-to-noise ratio. This is particularly the case when optical ports are located in close proximity to the heated zones, e.g., in flow cells in which optical access must not lead to perturbations of the gas flow and temperature. To reduce beam steering, an optical port arrangement involving a pair of transparent windows with an intervening vacuum as disclosed herein (for transmission measurements, two optical ports may be employed for a total of two pairs of windows). One window is located in a heated zone while the second window is located in an area free of significant thermal gradients in the ambient gas. The second (cool) window is thermally isolated from the first (hot) window. The volume between the two windows may be evacuated so that the gas density in this volume is insufficient to produce significant variations in the refractive index, thereby minimizing beam steering.

### SUMMARY OF REFERENCE NUMERALS

2 Vapor source
3 Transport line to optical detector
4 Oven
5 Electromagnetic radiation or light source
6 Electromagnetic radiation or light propagation to optical detector
7 Sensor
8 Electromagnetic radiation or light propagation to sensor
9 Deposition process
10 Communication line to controller
11 Controller
12 Communication line to valve
13 Valve
14 Transport line to valve
15 Deposition chamber
16 Transport line to deposition chamber
17 Substrate
18 Bypass line to pump
19 Pump
20 Transport line to pump
23 Communication line to pump
100 Optical cell
101 Steered electromagnetic radiation or light beam path
102 Inner optical window
103 Straight electromagnetic radiation or light beam path
104 Outer optical window
106 Cell body
108 Connector
112 Heater
116 Connecting disc
118 Window holder
120 Vacuum chamber
121 Vacuum chamber
122 Vacuum port
124 Connecting disc
126 Window holder
128 Groove for seal
130 Absorbance plot, low temperature, no scintillation reducers
132 Absorbance plot, low temperature, scintillation reducers installed
134 Absorbance plot, high temperature, no scintillation reducers installed
136 Absorbance plot, high temperature, scintillation reducers installed

1. An apparatus configured to monitor low vapor pressure precursor flux in a semiconductor deposition process comprising:
an optical cell configured for optical spectroscopy comprising:
a precursor reservoir or deposition chamber configured to provide a flow of a low vapor deposition precursor therethrough;
a first inner window sealing a first optical opening in said precursor reservoir or deposition chamber;
a first outer window in optical communication with said first inner window;
a first vacuum chamber disposed between said first inner window and said first outer window;
a second inner window sealing a second optical opening in said precursor reservoir or deposition chamber;
a second outer window in optical communication with said second inner window;
a second vacuum chamber disposed between said second inner window and said second outer window;
said first inner window, said first outer window, said second inner window, and said second outer window each being disposed to be in optical communication with one another; and
said apparatus further comprising a electromagnetic radiation source disposed in optical communication with said first outer window or said second outer window and an electromagnetic radiation detector disposed in optical communication with the other of said first outer window or said second outer window.

2. The apparatus configured to monitor low vapor pressure precursor flux in a semiconductor deposition process of claim 1 further comprising a heater configured and disposed to heat said precursor reservoir or deposition chamber.

3. The apparatus configured to monitor low vapor pressure precursor flux in a semiconductor deposition process of claim 2 wherein said first vacuum chamber and said second vacuum chamber each comprise a vacuum port.

4. The apparatus configured to monitor low vapor pressure precursor flux in a semiconductor deposition process of claim 1 wherein said semiconductor deposition process comprises a controller in data communication with said electromagnetic radiation detector and configured to control at least one of a) and b):
a) the flux of the precursor into a semiconductor deposition chamber; and
b) at least one operating parameter of a semiconductor deposition chamber.

5. The apparatus configured to monitor low vapor pressure precursor flux in a semiconductor deposition process of claim 1 wherein said semiconductor deposition process is a CVD or ALD process.

6. An apparatus configured to monitor precursor flux in a semiconductor deposition process comprising:
a cell configured for electromagnetic radiation spectroscopy comprising:
a precursor reservoir or deposition chamber configured to provide a flow of a vapor deposition precursor therethrough;
a first inner window sealing a first optical opening in said precursor reservoir or deposition chamber;
a first outer window in optical communication with said first inner window;
a vacuum chamber disposed between said first inner window and said first outer window;
a second inner window sealing a second optical opening in said precursor reservoir or deposition chamber;
said first inner window, said first outer window, and said second inner window, each being disposed to be in optical communication with one another; and
said apparatus further comprising an electromagnetic radiation source in optical communication with said first outer window or said second inner window and an electromagnetic radiation detector in optical communication with the other of said first outer window or said second inner window.

7. The apparatus configured to monitor precursor flux in a semiconductor deposition process of claim 6 further comprising a heater configured and disposed to heat said precursor reservoir or deposition chamber.

8. The apparatus configured to monitor precursor flux in a semiconductor deposition process of claim 6 wherein said vacuum chamber comprises a vacuum port.

9. The apparatus configured to monitor precursor flux in a semiconductor deposition process of claim 6 wherein said semiconductor deposition process comprises a controller in data communication with said electromagnetic radiation detector and configured to control at least one of a) and b):
a) the flux of the precursor into a semiconductor deposition chamber; and
b) at least one operating parameter of a semiconductor deposition chamber.

10. The apparatus configured to monitor precursor flux in a semiconductor deposition process of claim 6 wherein said semiconductor deposition process is a CVD or ALD process.

11. The apparatus configured to monitor precursor flux in a semiconductor deposition process of claim 6 further comprising a second outer window in optical communication with said second inner window and a second vacuum chamber disposed between said second inner window and said second outer window, said electromagnetic radiation source being in optical communication with said first outer window or said second outer window and said electromagnetic radiation detector being in optical communication with the other of said with said first outer window or said second outer window.

12. The apparatus configured to monitor precursor flux in a semiconductor deposition process of claim 11 wherein said second vacuum chamber comprises a vacuum port.

13. The apparatus configured to monitor precursor flux in a semiconductor deposition process of claim 6 wherein an inner surface of said precursor reservoir or deposition chamber and an inner surface of said first and said second inner windows are configured to be nonreactive with a precursor therein.

14. The apparatus configured to monitor precursor flux in a semiconductor deposition process of claim 6 being configured to reduce beam steering of electromagnetic radiation energy passing through said cell by an amount sufficient for said electromagnetic radiation sensor to sense a low vapor pressure precursor at a high temperature.

15. The apparatus configured to monitor precursor flux in a semiconductor deposition process of claim 14 wherein said low vapor pressure precursor comprises an organometallic precursor.

16. The apparatus configured to monitor precursor flux in a semiconductor deposition process of claim 14 wherein said high temperature is at least 50° C.

17. The apparatus configured to monitor precursor flux in a semiconductor deposition process of claim 6 being configured to maintain a temperature of said first outer window lower than a temperature of said first inner window through a semiconductor deposition run.

18. A method of monitoring precursor flux comprising the steps of:
directing electromagnetic radiation through an outer window, a vacuum chamber, an first inner window, a volume within a cell body configured to have precursor therein, and out of the cell body through a second inner window;
receiving the electromagnetic radiation from the second inner window with a sensor configured to sense at least one parameter of the gas within the cell body; and
sensing at least one parameter of the gas within the cell body.

19. The method of monitoring precursor flux of claim 18 further comprising the steps of:
sending data from a sensor configured for sensing at least one parameter of the gas within the cell body to a controller; and
controlling at least one of a) and b):
a) the flux of the precursor into a semiconductor deposition chamber; and
b) at least one operating parameter of a semiconductor deposition chamber.

20. The method of monitoring precursor flux of claim 18 further comprising the step of maintaining a temperature of said first outer window below a temperature of said inner window throughout a semiconductor deposition run.
